(19) United States
(12) Patent Application Publication
(10) Pub. No.: US 2025/0354755 A1
(43) Pub. Date: Nov. 20, 2025

(54) SUBSTRATE PROCESSING APPARATUS

(71) Applicant: Samsung Electronics Co., Ltd., Suwon-si (KR)

(72) Inventors: DAE-WOONG CHOI, Suwon-si (KR); HYUN-CHUL KIM, Suwon-si (KR); Jinhong Park, Suwon-si (KR); OHCHEL KWON, Suwon-si (KR); Taeheon Kim, Suwon-si (KR); Harim Song, Suwon-si (KR)

(21) Appl. No.: 18/916,936

(22) Filed: Oct. 16, 2024

(30) Foreign Application Priority Data
May 17, 2024 (KR) 10-2024-0064615

(51) Int. Cl. F26B 21/10

(52) U.S. Cl. CPC F26B 21/10

(57) ABSTRACT

A substrate processing apparatus may include a drying housing having an internal space for performing a drying process, a process fluid supply configured to receive a process fluid used in the drying process, a supply fluid line connected to the drying housing and the process fluid supply, a pressure reducing fluid line connected to the supply fluid line, and a controller configured to control the operation of the substrate processing apparatus. The controller is configured to cause the supply of the process fluid to the drying housing through the supply fluid line to stop and discharge the process fluid remaining in the supply fluid line through the pressure reducing fluid line.

### CROSS-REFERENCE TO RELATED APPLICATION

This application claims priority to and the benefit of Korean Patent Application No. 10-2024-0064615 filed in the Korean Intellectual Property Office on May 17, 2024, the entire contents of which is incorporated herein by reference.

### BACKGROUND OF THE INVENTION

### (a) Field of the Invention

The present disclosure relates to a substrate processing apparatus capable of processing a substrate using a fluid in a supercritical state.

### (b) Description of the Related Art

A semiconductor device may be manufactured through various processes, including a photolithography process that forms circuit patterns on a substrate such as a silicon wafer. During the manufacturing process of a semiconductor device, various foreign substances such as particles, organic contaminants, and metal impurities may be generated. These foreign substances can cause defects in the substrate, directly affecting the performance and yield of the semiconductor device. Therefore, in the manufacturing process of a semiconductor device, a cleaning process may be performed to remove these foreign substances.

The cleaning process may be performed through a series of steps, including a chemical process that removes foreign substances from the substrate using chemicals, a rinse process that cleans the chemicals off with pure water, and a drying process that dries the substrate.

### SUMMARY OF THE INVENTION

The present disclosure describes a substrate processing apparatus that reduces the generation of defects during a substrate drying process.

However, the objective of the inventive concept is not limited to the aforementioned one, and the described embodiments may be extended in various ways.

A substrate processing apparatus may include a drying housing having an internal space for performing a drying process, a process fluid supply configured to receive a process fluid used in the drying process, a supply fluid line connected to the drying housing and connected to the process fluid supply, a pressure reducing fluid line connected to the supply fluid line, and a controller configured to control the operation of the substrate processing apparatus. The controller is configured to initiate a drying process and, after the drying process is initiated, cause the supply of the process fluid to the drying housing through the supply fluid line to stop and cause the process fluid remaining in the supply fluid line to discharge through the pressure reducing fluid line.

A substrate processing apparatus may include a drying housing having an internal space for performing a drying process, a process fluid supply configured to receive a process fluid used in the drying process, a supply fluid line connected to the drying housing and connected to the process fluid supply, a pressure reducing fluid line connected to the supply fluid line, and a controller configured to control the operation of the substrate processing apparatus. The controller is configured to stop a supply of the process fluid to the drying housing after an internal pressure of the drying housing has reached a first threshold pressure and discharge, process fluid remaining in the supply fluid line through the pressure reducing fluid line before resupplying the process fluid to the drying housing.

A substrate processing apparatus may include a drying housing having an internal space for performing a drying process, a process fluid supply configured to receive a process fluid used in the drying process, a supply fluid line connected to the drying housing and the process fluid supply, and a pressure reducing fluid line connected to the supply fluid line, where the supply fluid line may include a main fluid line having a first end connected to the process fluid supply, a first branch fluid line having a first end connected to a second end of the main fluid line, and a second end connected to the drying housing, and a second branch fluid line having a first end connected to the second end of the main fluid line, and a second end connected to the drying housing. The pressure reducing fluid line provides a fluid path for the process fluid to discharge from the supply fluid line.

A method of manufacturing a substrate may include performing a liquid processing process on a substrate in a liquid processing chamber, transferring the substrate to a drying chamber, and performing a drying process on the substrate in a drying housing of the drying chamber. The drying process includes supplying a process fluid in a supercritical state to a supply fluid line connected to the drying housing to supply the process fluid to the drying housing, determining that a pressure in the drying housing has reached a first threshold pressure, stopping the supply of the process fluid to the drying housing responsive to the pressure in the drying housing reaching the first threshold pressure, and reducing the pressure of the process fluid in the supply fluid line through a pressure reducing fluid line connected to the supply fluid line.

According to an embodiment, a substrate processing apparatus capable of preventing the generation of defects during the substrate drying process may be provided.

### BRIEF DESCRIPTION OF THE DRAWINGS

FIG. 1 is a top plan view of a substrate processing apparatus according to an embodiment.

FIG. 2 is a cross-sectional view of the liquid processing chamber of FIG. 1.

FIG. 3 is a drawing that represents the structure of a drying housing included in the drying chamber of FIG. 1 and a fluid line connected thereto.

FIG. 4 is a drawing that represents an internal pressure change of a drying housing while a drying process according to an embodiment is performed.

FIG. 5 is a drawing that represents a state of a drying chamber in which the process fluid is supplied to a drying housing in a pressure boosting step.

FIG. 6 is a drawing that represents a state of a drying chamber in which a pressure of an interior of a drying housing is being reduced in a flow step.

FIG. 7 is a drawing that represents a state of a drying chamber in which the process fluid is supplied to a drying housing in a flow step.

FIG. 8 is a drawing that represents a state of a drying chamber in which process fluid in an interior of a drying housing is discharged in a drying step.

FIG. 9 is a drawing that represents a fluid line structure connected to a drying housing according to another embodiment.

FIG. 10 is a drawing that represents a fluid line structure connected to a drying housing according to another embodiment.

FIG. 11 is a drawing that represents a fluid line structure connected to a drying housing according to another embodiment.

FIG. 12 is a drawing that represents a fluid line structure connected to a drying housing according to another embodiment.

FIG. 13 is a drawing that represents a fluid line structure connected to a drying housing according to another embodiment.

FIG. 14 is a drawing that represents a fluid line structure connected to a drying housing according to another embodiment.

FIG. 15 is a drawing that represents a state of a drying chamber in which a process fluid is supplied to a drying housing in the pressure boosting step described in FIG. 4.

FIG. 16 is a drawing that represents a state of a drying chamber in which the pressure is of an interior of a drying housing is being reduced in the flow step described in FIG. 4.

FIG. 17 is a drawing that represents a state of a drying chamber in which a process fluid is supplied to a drying housing in the flow step described in FIG. 4.

FIG. 18 is a drawing that represents an internal pressure change of a drying housing while a drying process is performed according to another embodiment.

FIG. 19 is a drawing that represents a state of a drying chamber in which a process fluid is supplied to a drying housing in the flow step described in FIG. 18.

FIG. 20 is a drawing that represents a fluid line structure connected to a drying housing according to another embodiment.

FIG. 21 is a drawing that represents a state of a drying chamber in which a process fluid is supplied to a drying housing in the pressure boosting step described in FIG. 4 or the pressure boosting step described in FIG. 18.

FIG. 22 is a drawing that represents a state of a drying chamber in which a process fluid is supplied to a drying housing in flow step.

FIG. 23 is a drawing that represents a fluid line structure connected to a drying housing according to another embodiment.

### DETAILED DESCRIPTION OF THE EMBODIMENTS

The inventive concept will be described more fully hereinafter with reference to the accompanying drawings, in which various embodiments are shown. As those skilled in the art would realize, the described embodiments May be modified in various different ways, all without departing from the spirit or scope of the inventive concept.

In order to clearly describe the embodiment, parts or portions that may be irrelevant to the inventive concept or commonly understood to those skilled in the art may be omitted, and identical or similar constituent elements throughout the specification may be denoted by the same reference numerals.

Further, in the drawings, the size and thickness of each element are arbitrarily illustrated for ease of description, and the present invention is not necessarily limited to those embodiments illustrated in the drawings. In the drawings, the thicknesses of layers, films, panels, regions, areas, etc., may be exaggerated for clarity. In the drawings, for ease of description, the thicknesses of some layers and areas may be exaggerated.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

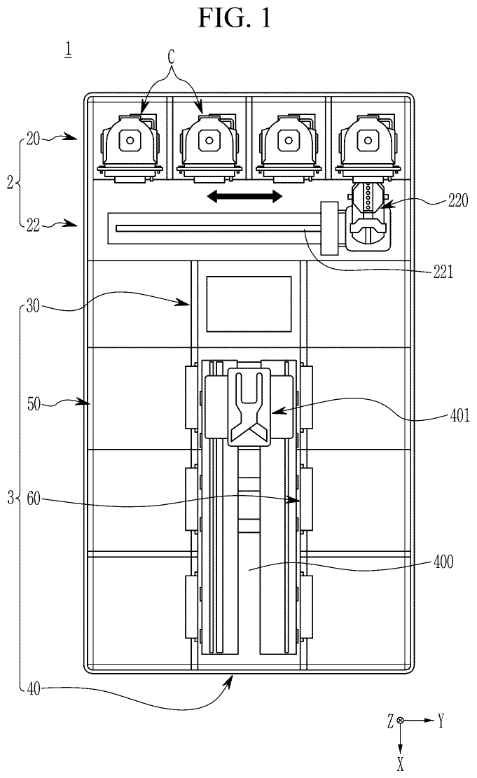

FIG. 1 is a top plan view of a substrate processing apparatus 1 according to an embodiment.

Referring to FIG. 1, the substrate processing apparatus 1 according to an embodiment may include an index module 2 and a process module 3.

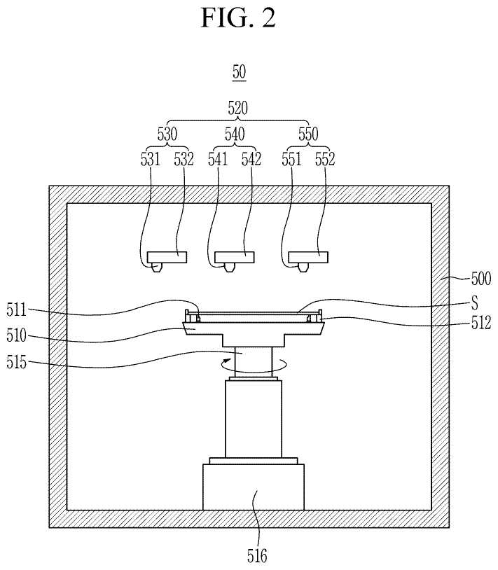

The index module 2 may allow a substrate (S of FIG. 2) to be carried in or out between the process module 3 and the outside. The index module 2 may be an equipment front end module (EFEM). The index module 2 may include a load port 20 and a transport 22.

The load port 20, the transport 22 and the process module 3 may be sequentially arranged in line. Here, a direction in which the load port 20, the transport 22 and the process module 3 are arranged may be called a first direction X, and in a top view, a direction perpendicular to the first direction X may be referred to as called a second direction Y, and a direction perpendicular to the first direction X and the second direction Y may be referred to as called a third direction Z. In addition, the third direction Z may be called a height direction.

At least one load port 20 may be provided in the index module 2. The load port 20 may be disposed on a first side of the transport 22. When the load port 20 is provided in a plural quantity, a plurality of load ports 20 may be arranged in line along the second direction Y. The number of the load port 20 and its arrangement form may not be limited to the above-described examples, and may be changed according to the footprint, process efficiency, arrangement relationship with respect to other devices, or the like, of the substrate processing apparatus 1. The load port 20 may have a carrier C located thereon, in which a substrate S is accommodated. The carrier C may be transported from the outside and loaded onto the load port 20. In addition, the carrier C may be unloaded from the load port 20 and transported to the outside. For example, the carrier C may be transported by a transport apparatus such as an overhead hoist transfer (OHT). In addition, the transport of the carrier C may be performed by an automatic guided vehicle, a rail-guided vehicle, or the like, or may be performed by a worker. The carrier C may accommodate the substrate S. The carrier C may be a front-opening unified pod (FOUP), or the like.

The transport 22 may be disposed between the load port 20 and the process module 3, and may transport the substrate S between the load port 20 and the process module 3. The transport 22 may include an index robot 220 and an index rail 221.

The index robot 220 may pick up the substrate S, and may transport the substrate S. The index rail 221 may provide a path along which the index robot 220 moves. The index rail 221 may extend in the second direction Y such that its length direction may correspond to an arrangement direction of the plurality of load ports 20. The index robot 220 may be installed on the index rail 221, and may move along the index rail 221. Accordingly, the index robot 220 may move along the second direction Y on the index rail 221, and draw out the substrate S from the carrier C located on the load port 20 and introduce it into the process module 3, or draw out the substrate S from the process module 3 and accommodate it into the carrier C located on the load port 20.

In addition, the index rail 221 may be omitted. In this case, the index robot 220 may be disposed in a central portion of the transport 22.

The process module 3 may perform a predetermined process on the introduced substrate S. The process performed by the process module 3 may be a cleaning process. The process module 3 may include a buffer chamber 30, a transport chamber 40 and process chambers 50 and 60.

The buffer chamber 30 and the transport chamber 40 may be disposed along the first direction X. The transport chamber 40 may be disposed such that its length direction may be oriented toward the first direction X. The process chambers 50 and 60 may process the substrate. The process chambers 50 and 60 may be disposed to be connected to the transport chamber 40. The process chambers 50 and 60 may include a liquid processing chamber 50 and a drying chamber 60. The liquid processing chamber 50 may be connected to the transport chamber 40. The drying chamber 60 may be connected to the transport chamber 40. The liquid processing chamber 50 and the drying chamber 60 may be disposed on a side surface of the transport chamber 40 in the second direction Y. For example, the liquid processing chamber 50 may be disposed on a first side of the transport chamber 40 in the second direction Y, and the drying chamber 60 may be disposed on a second side of the transport chamber 40 in the second direction Y (i.e., an opposite side of the direction in which the liquid processing chamber 50 is disposed).

The transport chamber 40 may include a transport rail 400 and a transport robot 401.

The transport rail 400 may provide a path along which the transport robot 401 moves. The length direction of the transport rail 400 may be oriented toward the first direction X.

The transport robot 401 may move on the transport rail 400, and may transport the substrate S between the buffer chamber 30, the liquid processing chamber 50 and the drying chamber 60.

The liquid processing chamber 50 may be provided in a singular or plural quantity. When the liquid processing chamber 50 is provided in a plural quantity, a plurality of liquid processing chambers 50 may be disposed along the first direction X, to be parallel to the length direction of the transport chamber 40. In addition, the plurality of liquid processing chambers 50 may be disposed to be stacked along the third direction. In addition, the plurality of liquid processing chambers 50 may be disposed as a combination of an arrangement along the first direction X and an arrangement along the third direction Z.

The drying chamber 60 may be provided in a singular or plural quantity. When the drying chamber 60 is provided in a plural quantity, a plurality of drying chambers 60 may be disposed along the first direction X, to be parallel to the length direction of the transport chamber 40. In addition, the plurality of drying chambers 60 may be disposed to be stacked along the third direction. In addition, the plurality of drying chambers 60 may be disposed as a combination of an arrangement along the first direction X and an arrangement along the third direction Z.

The drying chamber 60 may perform a drying process of the substrate S. A liquid processing process performed in the liquid processing chamber 50 and the drying process performed in the drying chamber 60 may be processes that are sequentially performed on a substrate. In some embodiments, the liquid processing process may be performed on a first substrate in the liquid processing chamber 50 at the same time that a drying process is performed on a second substrate in the drying chamber. In addition, the liquid processing process performed in the liquid processing chamber 50 and the drying process performed in the drying chamber 60 may, in some cases, be selectively performed such that only the first process is carried out.

The arrangement of the buffer chamber 30, the transport chamber 40, the liquid processing chamber 50, and the drying chamber 60 is not limited to the above-described example and may be modified to consider process efficiency. For example, the liquid processing chamber 50 and the drying chamber 60 may be disposed along the first direction X on the same side surface as the transport chamber 40, or may be disposed to be stacked with each other.

The buffer chamber 30 may be disposed between the index module 2 and the transport chamber 40. The buffer chamber 30 may be disposed between the transport 22 and the transport chamber 40. The buffer chamber 30 may allow the substrate S, which is transported between the index module 2 and the process module 3, to temporarily stay. Accordingly, the buffer chamber 30 may decrease the congestion that occurs during the transport of the substrate S and may ensure that the substrate S is effectively transported.

FIG. 2 is a cross-sectional view of the liquid processing chamber 50 of FIG. 1.

Referring to FIG. 2, the liquid processing chamber 50 may include a liquid processing housing 500, a support plate 510 and a fluid supply 520.

The liquid processing chamber 50 may perform the liquid processing process using chemicals to process the substrate S. For example, the liquid processing chamber 50 may perform a chemical process, a rinse process, and an organic solvent substitution process. The liquid processing housing 500 may provide an enclosed, internal space (e.g., the interior of the liquid processing housing) where the processing of the substrate S takes place.

The support plate 510 may be disposed in the interior of the liquid processing housing 500. The support plate 510 may support the substrate S. The support plate 510 may be rotated around the axis of the third direction Z. For example, a lower portion of the support plate 510 may be connected to an upper portion of a support shaft 515. A lower portion of the support shaft 515 may be connected to a drive 516. The support shaft 515 may be rotated by the power that the drive 516 provides.

A plurality of support pins 511 may be disposed on the support plate 510. The support pin 511 may be provided to protrude in the third direction Z on an upper surface of the support plate 510. The plurality of support pins 511 may be disposed to be spaced apart with a predetermined interval with each other. For example, the plurality of support pins 511 may be arranged on an annular ring having a predetermined radius. When the substrate S is located on the support plate 510, a bottom surface of the substrate S may be placed on the support pin 511.

A plurality of chucking pins 512 may be disposed on the support plate 510. The chucking pins 512 may be provided to protrude in the third direction Z on the upper surface of the support plate 510. A length of the chucking pins 512 in the third direction Z may be provided to be longer than the support pins 511, and accordingly, an upper end of the chucking pins 512 may be located above an upper end of the support pins 511. The chucking pins 512 may be disposed at a position away from a center of the support plate 510 that is farther from the center of the support plate 510 than the support pins 511. The chucking pins 512 may move between a fixed position and a pick-up position along a radius direction of the support plate 510. Here, the fixed position may be a position offset from the center of the support plate 510 by a distance corresponding to a radius of the substrate S, and the pick-up position may be a position offset from the center of the support plate 510 farther than the fixed position. When the substrate S is loaded on the support plate 510 by the transport robot 401, the chucking pins 512 may be located at the pick-up position. When the substrate S is loaded on the support plate 510, the chucking pins 512 may move to the fixed position, and may contact a side surface of the substrate S to fix the substrate S while the process is being performed. Accordingly, the chucking pins 512 may prevent the substrate S from being separated from the support plate 510 by rotational force when the support plate 510 rotates. When the process is finished, the chucking pins 512 may move to the pick-up position, and the transport robot 401 may pick up the substrate S.

The fluid supply 520 may supply the fluid for processing the substrate S to the support plate 510. Accordingly, the fluid for processing the substrate S may be applied to the substrate S located on the support plate 510. The fluid supply 520 may include nozzles 531, 541, and 551 and nozzle supports 532, 542, and 552.

The nozzles 531, 541, and 551 may spray the fluid for processing the substrate S. The nozzle supports 532, 542, and 552 may be connected to the nozzles 531, 541, and 551. The nozzle supports 532, 542, and 552 may move the positions of the nozzles 531, 541, and 551. Accordingly, the nozzles 531, 541, and 551 may move between a process position and a standby position. The process position may be a position at which the nozzles 531, 541, and 551 face the support plate 510 in the third direction Z. The standby position may be a position out of a region where the nozzles 531, 541, and 551 face the support plate 510 in the third direction Z.

The fluid supply 520 may include a chemical fluid supply 530, a rinse fluid supply 540 and a substitution fluid supply 550. The chemical fluid supply 530, the rinse fluid supply 540 and the substitution fluid supply 550 may spray different fluids.

The chemical fluid supply 530 may include a chemical nozzle 531 and a chemical nozzle support 532.

The chemical nozzle 531 may spray a chemical. The chemical may be a cleaning solution. For example, the chemical may be a hydrogen peroxide solution, a solution of mixing ammonia, hydrochloric acid or sulfuric acid into the hydrogen peroxide solution, hydrofluoric acid solution, or the like. The chemical nozzle support 532 may be connected to the chemical nozzle 531. The chemical nozzle support 532 may move the chemical nozzle 531 to the standby position and the process position.

The rinse fluid supply 540 may include a rinse nozzle 541 and a rinse nozzle support 542. The rinse nozzle 541 may spray a rinse solution. The rinse solution may be an ultrapure water, or the like. The rinse nozzle support 542 may be connected to the rinse nozzle 541. The rinse nozzle support 542 may move the rinse nozzle 541 to the standby position and the process position. After the chemical is supplied to the substrate S, the rinse fluid supply 540 may supply the rinse solution to the substrate S to remove the chemical remaining in the substrate S.

The substitution fluid supply 550 may include a substitution nozzle 551 and a substitution nozzle support 552. The substitution nozzle 551 may spray an organic solvent. The organic solvent may be isopropyl alcohol, ethyl glycol, 1-propanol, tetra hydraulic franc, 4-hydroxy(hydroxyl), 4-methyl, 2-pentanone, 1-butanol, 2-butanol, methanol, ethanol, n-propyl alcohol, dimethyl ether), or the like.

The substitution nozzle support 552 may be connected to the substitution nozzle 551. The substitution nozzle support 552 may move the substitution nozzle 551 to the standby position and the process position. After the rinse solution is supplied to the substrate S, the substitution fluid supply 550 may supply the organic solvent to the substrate S such that the rinse solution remaining in the substrate S may be replaced with the organic solvent.

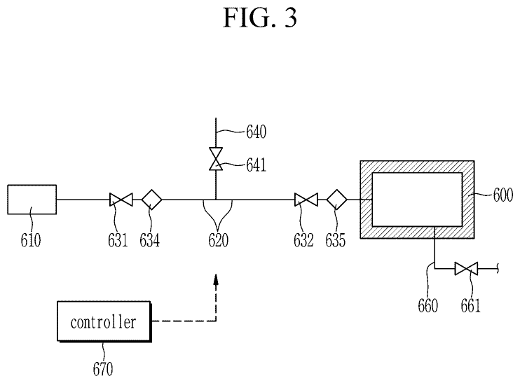

FIG. 3 is a drawing that represents the structure of a drying housing 600 included in the drying chamber 60 of FIG. 1 and a fluid line connected thereto.

Referring to FIG. 3, the drying chamber 60 may dry the substrate S using a fluid in a supercritical state. The drying chamber 60 may include the drying housing 600.

A space for performing the drying process may be located inside the drying housing 600 (e.g., the drying housing 600 may have an internal space for performing the drying process). The drying housing 600 may be provided with a pressure-withstanding structure capable of withstanding a high pressure.

The drying housing 600 may be connected to a process fluid supply 610 through a supply fluid line 620. The process fluid supply 610 may receive and/or store the process fluid for performing the drying process in the drying housing 600. For example, the process fluid supply may be a gas container storing the process fluid. In another example, the process fluid supply may be a connector configured to connect to a supply of the process fluid, such as a container storing the process fluid or an external source of the process fluid. The process fluid supply 610 may supply the process fluid in the supercritical state (e.g., the process fluid may be in a supercritical state). The process fluid may be supplied to the process fluid supply in the supercritical state, or the process fluid supply may convert the process fluid to be in the supercritical state. For example, the process fluid supply 610 may convert the process fluid into the supercritical state by heating the process fluid to a supercritical threshold temperate or more and pressurizing the process fluid to a supercritical threshold pressure or more. The process fluid supply may include a heating element and/or a compressor for heating and compressing the process fluid. The process fluid may be carbon dioxide or the like. The process fluid in the supercritical state generated in the process fluid supply 610 may be supplied to the drying housing 600 through the supply fluid line 620.

Hereinafter, when referring to the supply fluid line 620, during the time when the process fluid is supplied from the process fluid supply 610 to the drying housing 600, a direction from which the process fluid is introduced may be called an upstream direction, and a direction to which the process fluid flows may be called a downstream direction. That is, based on a point in the supply fluid line 620, a first side toward the process fluid supply 610 may be the upstream side, and a second, opposite side toward the drying housing 600 may be the downstream side.

Valves 631 and 632 may be disposed in the supply fluid line 620. When the valves 631 and 632 are opened, the process fluid may pass through the valves 631 and 632 and flow along the supply fluid line 620. When the valves 631 and 632 are closed, the valves 631 and 632 may block a flow of the process fluid in the supply fluid line 620. The valves 631 and 632 may include an upstream valve 631 and a downstream valve 632. The upstream valve 631 and the downstream valve 632 may be disposed to be spaced apart from each other in the supply fluid line 620. The downstream valve 632 may be disposed at a downstream side of the upstream valve 631. For example, the upstream valve 631 may be disposed in an upstream end portion of the supply fluid line 620, to be adjacent to the process fluid supply 610. The downstream valve 632 may be disposed in a downstream end portion of the supply fluid line 620, to be adjacent to the drying housing 600.

Filters 634 and 635 may be disposed in the supply fluid line 620. The filters 634 and 635 may filter foreign substances included with the process fluid flowing through the supply fluid line 620. The filters 634 and 635 may include an upstream filter 634 and a downstream filter 635. The upstream filter 634 may be disposed at a downstream side of the upstream valve 631. The upstream filter 634 may be disposed adjacent to the upstream valve 631, and may be disposed at an upstream side of the downstream valve 632. The downstream filter 635 may be disposed at a downstream side of the downstream valve 632.

A pressure reducing fluid line 640 may be connected to the supply fluid line 620. The pressure reducing fluid line 640 is branched from the supply fluid line 620, and may enable the process fluid to be discharged out of the supply fluid line 620. The pressure reducing fluid line 640 may be connected to the supply fluid line 620 in a section between the upstream valve 631 and the downstream valve 632. The pressure reducing fluid line 640 may be connected to the supply fluid line 620 in a section between the upstream filter 634 and the downstream valve 632. A pressure reducing valve 641 may be located on the pressure reducing fluid line 640. When the pressure reducing valve 641 is opened, the process fluid may flow from the supply fluid line 620 toward the pressure reducing fluid line 640. The pressure reducing valve 641 is closed, the flow of the process fluid from the supply fluid line 620 toward the pressure reducing fluid line 640 may be blocked.

A vent fluid line 660 may be connected to the drying housing 600. The vent fluid line 660 may discharge used process fluid from the interior of the drying housing 600. When the process fluid, the fluid removed from the substrate through the drying process, or the like is discharged from the interior of the drying housing 600 through the vent fluid line 660, the interior of the drying housing 600 may have a reduced pressure relative to when the fluid is not being discharged. A vent valve 661 may be located in the vent fluid line 660. When the vent valve 661 is opened, the process fluid may pass through the vent valve 661 and flow along the vent fluid line 660. The vent valve 661 is closed, the vent valve 661 may block the flow of the process fluid in the vent fluid line 660.

The substrate processing apparatus may include a controller 670 for controlling various operations of the substrate processing apparatus. For example, the controller 670 may communicate with the various valves, sensors, and other components of the substrate processing apparatus and may receive data and/or transmit data and/or control signals to the various valves, sensors, and other components of the substrate. In the figures, the dashed line connected to the controller 670 represents a communication connection (which may be wired or wireless) of the controller 670 to the carious elements to be controlled. For example, the controller 670 may send a control signal to a valve to cause the valve to open, close, or change to an intermediate state between an open state and a closed state. The controller 670 may communicate with a pressure sensor and open/and or close a valve responsive to the pressure sensor sensing a pressure crossing a threshold pressure. In other examples, a valve may be manually controlled by an operator.

Although not illustrated, a controller can include one or more of the following components: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the controller (e.g., keyboard, mouse, display, speakers, printers, modems, network cards, etc.), and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. In addition, the controller can include antennas, network interfaces that provide wireless and/or wire line digital and/or analog interface to one or more networks over one or more network connections (not shown), a power source that provides an appropriate alternating current (AC) or direct current (DC) to power one or more components of the controller, and a bus that allows communication among the various disclosed components of the controller.

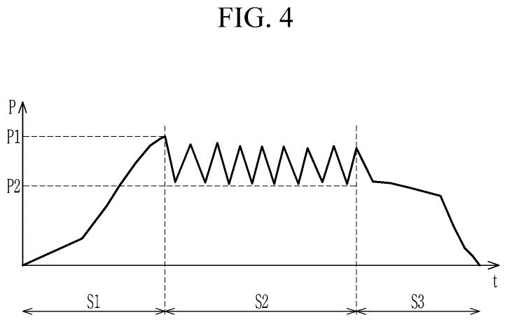

FIG. 4 is a drawing that represents an internal pressure change of the drying housing 600 during the drying process according to an embodiment.

Referring to FIG. 4, during the time that the drying process according to an embodiment, an internal pressure of the drying housing 600 may be changed in a sequence of a pressure boosting step S1, a flow step S2, and a vent step S3. The steps may be performed manually by and operator or may be performed by the control unit of the substrate processing apparatus.

During the pressure boosting step S1, the internal pressure of the drying housing 600 may be increased. For example, during the pressure boosting step S1, the internal pressure of the drying housing 600 may be increased to a first pressure P1. The first pressure P1 may be a value exceeding a threshold pressure of the process fluid. For example, the first pressure P1 may be 150 bar.

During the flow step S2, the internal pressure of the drying housing 600 may maintain at a pressure within a predetermined range. During the flow step S2, the internal pressure of the drying housing 600 may maintain a pressure between the first pressure P1 and a second pressure P2. The second pressure P2 may be a pressure lower than the first pressure P1. The second pressure P2 may be a pressure exceeding the threshold pressure of the process fluid. During the flow step S2, the internal pressure of the drying housing 600 may fall and rise at least once and may do so repeatedly. In FIG. 4, an example is shown where the internal pressure of the drying housing 600 falls and rises multiple times.

During the vent step S3, the internal pressure of the drying housing 600 is lowered. During the vent step S3, the internal pressure of the drying housing 600 may be lowered below the threshold pressure of the process fluid. For example, during the vent step S3, the internal pressure of the drying housing 600 may be lowered to a normal pressure (e.g., non-supercritical).

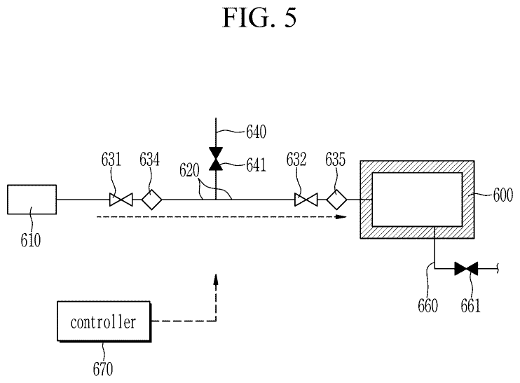

FIG. 5 is a drawing that represents a state of the drying chamber in which the process fluid is supplied to the drying housing 600 in the pressure boosting step S1.

Referring to FIG. 5, during the pressure boosting step S1, the valves 631 and 632 may both be opened, and the process fluid may be supplied from the process fluid supply 610 to the drying housing 600. During this time, the pressure reducing valve 641 may maintain a closed state, and the process fluid may be blocked from flowing from the supply fluid line 620 to the pressure reducing fluid line 640. In addition, the vent valve 661 may maintain the closed state, and a discharge of the process fluid through the vent fluid line 660 may be blocked. As time passes while the process fluid is supplied to the drying housing 600 during the pressure boosting step S1, the internal pressure of the drying housing 600 may increase. The supply of the process fluid may continue until the internal pressure of the drying housing 600 reaches the first pressure P1. In the pressure boosting step S1, a flow amount of the process fluid flowing along the supply fluid line 620 may be constant, or may vary according to time.

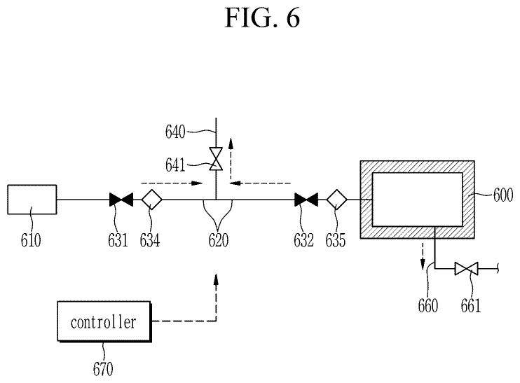

FIG. 6 is a drawing that represents a state of the drying chamber in which pressure reduction is being made in the interior of the drying housing 600 in the flow step S2.

Referring to FIG. 6, when the internal pressure of the drying housing 600 reaches the first pressure P1, the valves 631 and 632 may be closed, and the supply of the process fluid from the process fluid supply 610 to the drying housing 600 may be blocked. In addition, the vent valve 661 may be opened, and at least some of the process fluid in the interior of the drying housing 600 may be discharged through the vent fluid line 660. Accordingly, the internal pressure of the drying housing 600 is lowered. The discharge of the process fluid through the vent fluid line 660 may be made until the internal pressure of the drying housing 600 reaches a predetermined pressure, or may be made for a preset time.

In the state that the supply of the process fluid from the process fluid supply 610 to the drying housing 600 is blocked, the pressure reducing valve 641 may be opened, and the process fluid may flow from the supply fluid line 620 toward the pressure reducing fluid line 640. Specifically, during the state that the upstream valve 631 and the downstream valve 632 are closed, the pressure reducing valve 641 may be opened. Accordingly, the process fluid remaining in a section between the upstream valve 631 and the downstream valve 632 may be discharged through the pressure reducing fluid line 640. In the state that the supply of the process fluid to the drying housing 600 is blocked as the valves 631 and 632 are closed, the time when the pressure reducing valve 641 is open may be the same as the time when the vent valve 661 is open. That is, when the interior of the drying housing 600 is discharged through the vent fluid line 660, the discharge of the process fluid remaining in the supply fluid line 620 may be made through the pressure reducing fluid line 640. In addition, in the state in which the supply of the process fluid to the drying housing 600 is blocked as the valves 631 and 632 are closed, the time when the pressure reducing valve 641 is open may be different from the time when the vent valve 661 is open. That is, when the interior of the drying housing 600 is discharged through the vent fluid line 660, the pressure reducing valve 641 may be open during the time corresponding to a part of the time when the vent valve 661 is open.

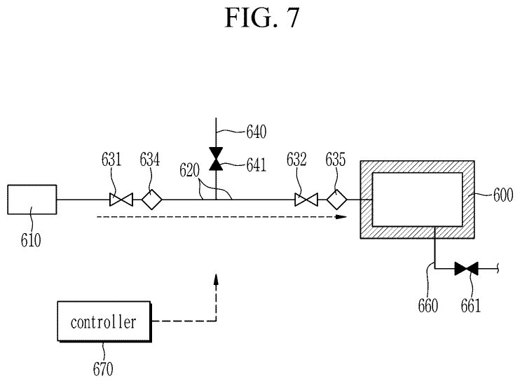

FIG. 7 is a drawing that represents a state of the drying chamber 60 in which the process fluid is supplied to the drying housing 600 in the flow step S2.

Referring to FIG. 7, during the flow step S2, the valves 631 and 632 may be opened again, and the process fluid may be supplied to the drying housing 600. In addition, the pressure reducing valve 641 may be closed, and the process fluid may be blocked from escaping through the pressure reducing fluid line 640. In addition, the vent valve 661 may be closed, and the interior of the drying housing 600 may be blocked from being discharged. Accordingly, the pressure of the drying housing 600 may increase.

The supply of the process fluid may continue until the internal pressure of the drying housing 600 reaches the predetermined pressure, or may be made for a preset time.

During the flow step S2, the process described in FIG. 6 and FIG. 7 may be repeated at least once. Accordingly, during the flow step S2, the internal pressure of the drying housing 600 may maintain a pressure between the first pressure P1 and the second pressure P2. In addition, during the process of discharging of the interior of the drying housing 600 and supplying the process fluid to the interior of the drying housing 600, a flow of the process fluid may occur in the interior of the drying housing 600 (e.g., the process fluid may continue to flow in the drying housing 600 rather than stagnating in the drying housing). Accordingly, the efficiency of the drying process may be prevented from being deteriorated from the process fluid stagnating around the substrate S. In addition, fluid is removed from the substrate S during the discharging process of the interior of the drying housing 600, and the drying efficiency may increase.

During the flow step S2, during a the time when the supply of the process fluid to the drying housing 600 through the supply fluid line 620 is stopped, the process fluid remaining in the supply fluid line 620 may change from the supercritical state to the gas state. If the process fluid in the gas state flows into the drying housing 600, the efficiency of the drying process is lowered. In addition, deterioration of the efficiency of the drying process may cause a drying defect, a yield decrease, or the like.

In the substrate processing apparatus 1 according to an embodiment, after the drying process is initiated, the process fluid remaining in the supply fluid line 620 may be discharged through the pressure reducing fluid line 640 during the time when the supply of the process fluid to the drying housing 600 through the supply fluid line 620 is stopped. Accordingly, when the process fluid is supplied again to the drying housing 600, flowing of the process fluid in the gas state into the drying housing 600 may be prevented or minimized.

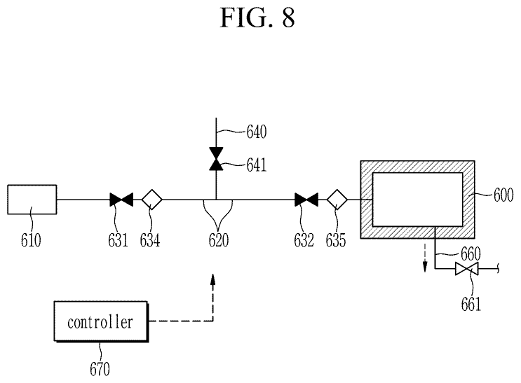

FIG. 8 is a drawing that represents a state of the drying chamber in which the interior of the drying housing 600 is discharged in a drying step.

Referring to FIG. 8, after the flow step S2, the vent valve 661 may be opened, and the vent step S3 in which the interior of the drying housing 600 is discharged may be performed. During the vent step S3, the valves 631 and 632 may maintain the closed state, and the supply of the process fluid to the drying housing 600 may be blocked. In addition, during the vent step S3, the pressure reducing valve 641 may be in the closed state.

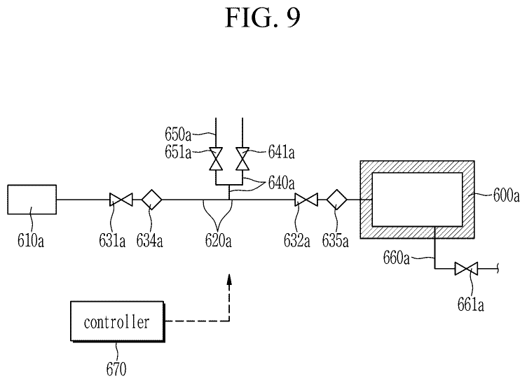

FIG. 9 is a drawing that represents a fluid line structure connected to a drying housing 600a according to another embodiment.

Referring to FIG. 9, the drying housing 600a may be connected to a process fluid supply 610a through a supply fluid line 620a. Valves 631a and 632a may be disposed in the supply fluid line 620a. The valves 631a and 632a may include an upstream valve 631a and a downstream valve 632a. Filters 634a and 635a may be disposed in the supply fluid line 620a. The filters 634a and 635a may include an upstream filter 634a and a downstream filter 635a.

A pressure reducing fluid line 640a may be connected to the supply fluid line 620a. A pressure reducing valve 641a may be located in the pressure reducing fluid line 640a.

A safety fluid line 650a may be connected to the pressure reducing fluid line 640a. The safety fluid line 650a is branched from the pressure reducing fluid line 640a, and may enable the process fluid to be discharged out of the supply fluid line 620a. The safety fluid line 650a may be connected to the pressure reducing fluid line 640a in a section between a first end of the pressure reducing fluid line 640a connected to the supply fluid line 620a and the pressure reducing valve 641a. A safety valve 651a may be disposed in the safety fluid line 650a. When a safety problem may arise as a pressure of the supply fluid line 620a becomes above the predetermined pressure, the safety valve 651a may be opened, to discharge the process fluid from the supply fluid line 620a. In addition, when the process fluid needs to be discharged from the supply fluid line 620a, e.g., in the maintenance and repair process of the substrate processing apparatus 1, the safety valve 651a may be opened, to discharge the process fluid from the supply fluid line 620a.

A vent fluid line 660a may be connected to the drying housing 600a. A vent valve 661a may be located on the vent fluid line 660a.

The structure and function of the process fluid supply 610a, the supply fluid line 620a, the valves 631a and 632a, the filters 634a and 635a, the pressure reducing fluid line 640a, the pressure reducing valve 641a, the vent fluid line 660a, and the vent valve 661a may be the same as or similar to the process fluid supply 610, the supply fluid line 620, the valves 631 and 632, the filters 634 and 635, the pressure reducing fluid line 640, the pressure reducing valve 641, the vent fluid line 660, and the vent valve 661, which are described in FIG. 3 to FIG. 8, and the description thereof which would be redundant is not included herein.

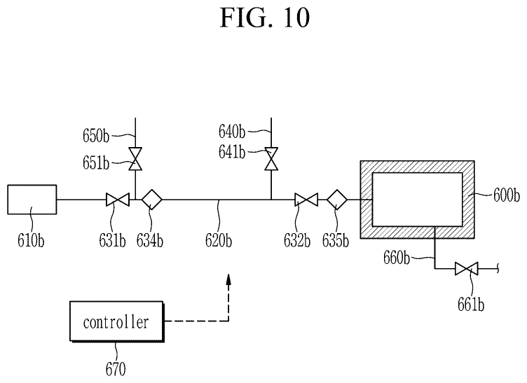

FIG. 10 is a drawing that represents a fluid line structure connected to a drying housing 600b according to another embodiment.

Referring to FIG. 10, the drying housing 600b may be connected to a process fluid supply 610b through a supply fluid line 620b. Valves 631b and 632b may be disposed in the supply fluid line 620b. The valves 631b and 632b may include an upstream valve 631b and a downstream valve 632b. Filters 634b and 635b may be disposed in the supply fluid line 620b. The filters 634b and 635b may include an upstream filter 634b and a downstream filter 635b.

A pressure reducing fluid line 640b may be connected to the supply fluid line 620b. A pressure reducing valve 641b may be located in the pressure reducing fluid line 640b.

A safety fluid line 650b may be connected to the supply fluid line 620b. The safety fluid line 650b is branched from the supply fluid line 620b, and may enable the process fluid to be discharged out of the supply fluid line 620b. The safety fluid line 650b may be connected to the supply fluid line 620b in a section between the upstream valve 631b and the downstream valve 632b. The safety fluid line 650b may be connected to the supply fluid line 620b at a point closer to the process fluid supply 610b than the pressure reducing fluid line 640b. The safety fluid line 650b may be connected to the supply fluid line 620b in a section between the upstream valve 631b and the upstream filter 634b. A safety valve 651b may be located in the safety fluid line 650b. When a safety problem may arise as a pressure of the supply fluid line 620b becomes above the predetermined pressure, the safety valve 651b may be opened, to discharge the process fluid from the supply fluid line 620b. In addition, when the process fluid needs to be discharged from the supply fluid line 620b, e.g., in the maintenance and repair process of the substrate processing apparatus 1, the safety valve 651b may be opened, to discharge the process fluid from the supply fluid line 620b.

A vent fluid line 660b may be connected to the drying housing 600b. A vent valve 661b may be located on the vent fluid line 660b.

The structure and function of the process fluid supply 610b, the supply fluid line 620b, the valves 631b and 632b, the filters 634b and 635b, the pressure reducing fluid line 640b, the pressure reducing valve 641b, the vent fluid line 660b, and the vent valve 661b may be the same as or similar to the process fluid supply 610, the supply fluid line 620, the valves 631 and 632, the filters 634 and 635, the pressure reducing fluid line 640, the pressure reducing valve 641, the vent fluid line 660, and the vent valve 661, which are described in FIG. 3 to FIG. 8, and the repeated description thereof which would be redundant is not redundantly included herein.

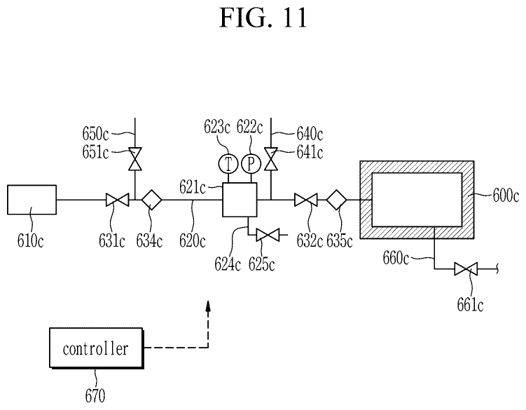

FIG. 11 is a drawing that represents a fluid line structure connected to a drying housing 600c according to another embodiment.

Referring to FIG. 11, the drying housing 600c may be connected to a process fluid supply 610c through a supply fluid line 620c. Valves 631c and 632c may be disposed in the supply fluid line 620c. The valves 631c and 632c may include an upstream valve 631c and a downstream valve 632c. Filters 634c and 635c may be disposed in the supply fluid line 620c. The filters 634c and 635c may include an upstream filter 634c and a downstream filter 635c.

A pressure reducing fluid line 640c may be connected to the supply fluid line 620c. A pressure reducing valve 641c may be located in the pressure reducing fluid line 640c.

An extension portion 621c may be located in the supply fluid line 620c. The extension portion 621c may be provided such that a size of an interior space along a direction perpendicular to the length direction of the supply fluid line 620c may be greater than that of an adjacent region (e.g., the cross section of the extension portion along a direction perpendicular to the length direction of the supply fluid line 620c may be greater than the cross section of an adjacent region). For example, the extension portion 621c may have a tank structure or the like having a volume of a predetermined size.

The extension portion 621c may be located in a section between the upstream valve 631c and the downstream valve 632c. The extension portion 621c may be located in a section between the upstream filter 634c and the downstream valve 632c. The extension portion 621c may be located at an upstream side of a point at which the pressure reducing fluid line 640c is connected to the supply fluid line 620c. The extension portion 621c may be located in a section between the point at which the pressure reducing fluid line 640c is connected to the supply fluid line 620c and the upstream filter 634c. The extension portion 621c may be located adjacent to the point at which the pressure reducing fluid line 640c is connected to the supply fluid line 620c, and thereby may decrease the noise occurring in the process of discharging the process fluid through the pressure reducing fluid line 640c. In addition, the extension portion 621c may prevent dew condensation generated due to a temperature drop in the process of discharging the process fluid through the pressure reducing fluid line 640c.

A pressure gauge 622c may be connected to the extension portion 621c. The pressure gauge 622c may detect a pressure of an interior of the extension portion 621c.

A thermometer 623c may be connected to the extension portion 621c. The thermometer 623c may detect a temperature of the interior of the extension portion 621c.

A management fluid line 624c may be connected to the extension portion 621c. A management valve 625c may be disposed in the management fluid line 624c. The management valve 625c may open and close the management fluid line 624c. When the process fluid needs to be discharged from the interior of the extension portion 621c, e.g., in the maintenance and repair process, the management valve 625c may be opened, to discharge the process fluid from the extension portion 621c through the management fluid line 624c.

A vent fluid line 660c may be connected to the drying housing 600c. A vent valve 661c may be located on the vent fluid line 660c.

The structure and function of the process fluid supply 610c, the supply fluid line 620c, the valves 631c and 632c, the filters 634c and 635c, the pressure reducing fluid line 640c, the pressure reducing valve 641c, the vent fluid line 660c, and the vent valve 661c may be the same as or similar to the process fluid supply 610, the supply fluid line 620, the valves 631 and 632, the filters 634 and 635, the pressure reducing fluid line 640, the pressure reducing valve 641, the vent fluid line 660, and the vent valve 661, which are described in FIG. 3 to FIG. 8, and the repeated description thereof which would be redundant is not redundantly included herein.

In the same or similar way as described in FIG. 10, a safety fluid line 650c may be connected to the supply fluid line 620c. A safety valve 651c may be located on the safety fluid line 650c. In addition, in the same or similar way as described in FIG. 9, the safety fluid line 650c may be connected to the pressure reducing fluid line 640c. In addition, the safety fluid line 650c may be omitted.

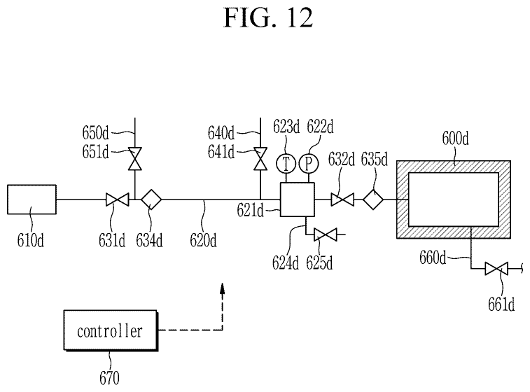

FIG. 12 is a drawing that represents a fluid line structure connected to a drying housing 600d according to another embodiment.

Referring to FIG. 12, the drying housing 600d may be connected to a process fluid supply 610d through a supply fluid line 620d. Valves 631d and 632d may be disposed in the supply fluid line 620d. The valves 631d and 632d may include an upstream valve 631d and a downstream valve 632d. Filters 634d and 635d may be disposed in the supply fluid line 620d. The filters 634d and 635d may include an upstream filter 634d and a downstream filter 635d.

A pressure reducing fluid line 640d may be connected to the supply fluid line 620d. A pressure reducing valve 641d may be located on the pressure reducing fluid line 640d.

An extension portion 621d may be located on the supply fluid line 620d. The extension portion 621d may be located in a section between the upstream valve 631d and the downstream valve 632d. The extension portion 621d may be located in a section between the upstream filter 634d and the downstream valve 632d. The extension portion 621d may be located on a downstream side of a point at which the pressure reducing fluid line 640d is connected to the supply fluid line 620d. The extension portion 621d may be located in a section between the point at which the pressure reducing fluid line 640d is connected to the supply fluid line 620d and the downstream valve 632d. The extension portion 621d may be located adjacent to the point at which the pressure reducing fluid line 640d is connected to the supply fluid line 620d, and thereby may decrease the noise occurring in the process of discharging the process fluid through the pressure reducing fluid line 640d. In addition, the extension portion 621d may prevent dew condensation generated due to a temperature drop in the process of discharging the process fluid through the pressure reducing fluid line 640d.

A pressure gauge 622d may be connected to the extension portion 621d. The pressure gauge 622d may detect a pressure of an interior of the extension portion 621d.

A thermometer 623d may be connected to the extension portion 621d. The thermometer 623d may detect a temperature of the interior of the extension portion 621d.

A management fluid line 624d may be connected to the extension portion 621d. A management valve 625d may be disposed in the management fluid line 624d.

A vent fluid line 660d may be connected to the drying housing 600d. A vent valve 661d may be located on the vent fluid line 660d.

The structure and function of the process fluid supply 610d, the supply fluid line 620d, the valves 631d and 632d, the filters 634d and 635d, the pressure reducing fluid line 640d, the pressure reducing valve 641d, the vent fluid line 660d, and the vent valve 661d may be the same as or similar to the process fluid supply 610, the supply fluid line 620, the valves 631 and 632, the filters 634 and 635, the pressure reducing fluid line 640, the pressure reducing valve 641, the vent fluid line 660, and the vent valve 661, which are described in FIG. 3 to FIG. 8, and the repeated description thereof which would be redundant is not redundantly included herein.

In addition, the structure of the extension portion 621d may be the same as or similar to the extension portion 621c described in FIG. 11, and the repeated description thereof which would be redundant is not redundantly included herein.

In the same or similar way as described in FIG. 10, a safety fluid line 650d may be connected to the supply fluid line 620d. A safety valve 651d may be located on the safety fluid line 650d. In addition, in the same or similar way as described in FIG. 9, the safety fluid line 650d may be connected to the pressure reducing fluid line 640d. In addition, the safety fluid line 650d may be omitted.

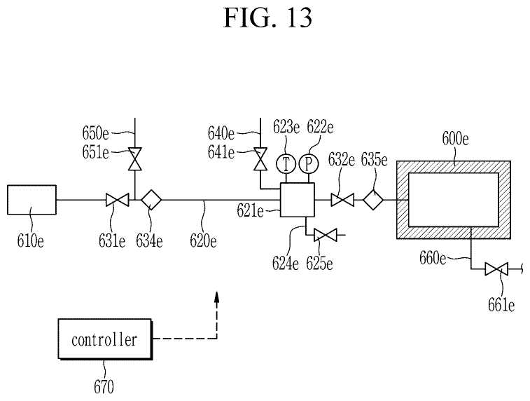

FIG. 13 is a drawing that represents a fluid line structure connected to a drying housing 600e according to another embodiment.

Referring to FIG. 13, the drying housing 600e may be connected to a process fluid supply 610e through a supply fluid line 620e. Valves 631e and 632e may be disposed in the supply fluid line 620e. The valves 631e and 632e may include an upstream valve 631e and a downstream valve 632e. Filters 634e and 635e may be disposed in the supply fluid line 620e. The filters 634e and 635e may include an upstream filter 634e and a downstream filter 635e.

A pressure reducing fluid line 640e may be connected to the supply fluid line 620e. A pressure reducing valve 641e may be located on the pressure reducing fluid line 640e.

An extension portion 621e may be located on the supply fluid line 620e. The extension portion 621e may be located in a section between the upstream valve 631e and the downstream valve 632e. The extension portion 621e may be located in a section between the upstream filter 634e and the downstream valve 632e.

The pressure reducing fluid line 640e may be connected to the extension portion 621e. The extension portion 621e may decrease the noise occurring in the process of discharging the process fluid through the pressure reducing fluid line 640e. In addition, the extension portion 621e may prevent dew condensation generated due to a temperature drop in the process of discharging the process fluid through the pressure reducing fluid line 640e.

A pressure gauge 622e may be connected to the extension portion 621e. The pressure gauge 622e may detect a pressure of an interior of the extension portion 621e.

A thermometer 623e may be connected to the extension portion 621e. The thermometer 623e may detect a temperature of the interior of the extension portion 621e.

A management fluid line 624e may be connected to the extension portion 621e. A management valve 625e may be disposed in the management fluid line 624e.

A vent fluid line 660e may be connected to the drying housing 600e. A vent valve 661e may be located on the vent fluid line 660e.

The structure and function of the process fluid supply 610e, the supply fluid line 620e, the valves 631e and 632e, the filters 634e and 635e, the pressure reducing fluid line 640e, the pressure reducing valve 641e, the vent fluid line 660e, and the vent valve 661e may be the same as or similar to the process fluid supply 610, the supply fluid line 620, the valves 631 and 632, the filters 634 and 635, the pressure reducing fluid line 640, the pressure reducing valve 641, the vent fluid line 660, and the vent valve 661, which are described in FIG. 3 to FIG. 8, and the repeated description thereof which would be redundant is not redundantly included herein.

In addition, the structure of the extension portion 621e may be the same as or similar to the extension portion 621c described in FIG. 11, and the repeated description thereof which would be redundant is not redundantly included herein.

In the same or similar way as described in FIG. 10, a safety fluid line 650e may be connected to the supply fluid line 620e. A safety valve 651e may be located on the safety fluid line 650e. In addition, in the same or similar way as described in FIG. 9, the safety fluid line 650e may be connected to the pressure reducing fluid line 640e. In addition, the safety fluid line 650e may be omitted.

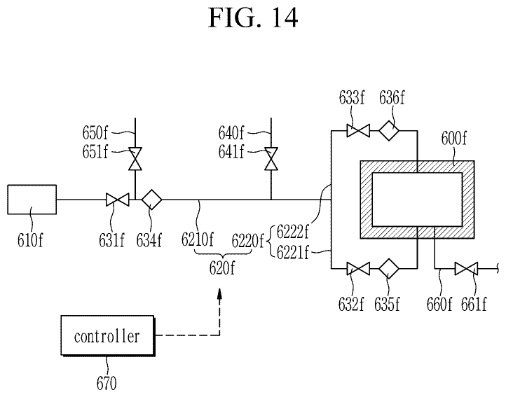

FIG. 14 is a drawing that represents a fluid line structure connected to a drying housing 600f according to another embodiment.

Referring to FIG. 14, the drying housing 600f may be connected to a process fluid supply 610f through a supply fluid line 620f. Hereinafter, repeated description on the part that is the same as or similar to that described in FIGS. 3 to FIG. 8 will not be redundantly included herein, and the description will focus on the differences.

The supply fluid line 620f may include a main fluid line 6210f and a branch fluid line 6220f.

A first end of the main fluid line 6210f may be connected to the process fluid supply 610f.

A first end of the branch fluid line 6220f may be connected to a second end of the main fluid line 6210f. A second end of the branch fluid line 6220f may be connected to the drying housing 600f. The branch fluid line 6220f may include a first branch fluid line 6221f and a second branch fluid line 6222f. The first branch fluid line 6221f and the second branch fluid line 6222f is branched from the second end of the main fluid line 6210f, and may be connected to the drying housing 600f in a in parallel structure. A second end of the first branch fluid line 6221f may be connected to a lower portion of the drying housing 600f. For example, the second end of the first branch fluid line 6221f may be connected to a lower wall of the drying housing 600f. A second end of the second branch fluid line 6222f may be connected to an upper portion of the drying housing 600f. For example, the second end of the second branch fluid line 6222f may be connected to an upper wall of the drying housing 600f.

Valves 631f, 632f, and 633f may be disposed in the supply fluid line 620f. The valves 631f, 632f, and 633f may include an upstream valve 631f and the downstream valves 632f and 633f. The upstream valve 631f and the downstream valves 632f and 633f may be disposed to be spaced apart from each other on the supply fluid line 620f. The upstream valve 631f may be disposed in an upstream side of the downstream valves 632f and 633f. The upstream valve 631f may be disposed in the main fluid line 6210f.

The downstream valves 632f and 633f may be disposed in the branch fluid line 6220f. The downstream valves 632f and 633f may include a first downstream valve 632f and a second downstream valve 633f. The first downstream valve 632f may be disposed in the first branch fluid line 6221f. The second downstream valve 633f may be disposed in the second branch fluid line 6222f.

Filters 634f, 635f, and 636f may be disposed in the supply fluid line 620f. The filters 634f, 635f, and 636f may filter foreign substances included in the process fluid flowing through the supply fluid line 620f. The filters 634f, 635f, and 636f may include an upstream filter 634f and the downstream filters 635f and 636f. The upstream filter 634f may be disposed in the main fluid line 6210f. The upstream filter 634f may be disposed in a downstream side of the upstream valve 631f.

The downstream filters 635f and 636f may be disposed in the branch fluid line 6220f. The downstream filters 635f and 636f may include a first downstream filter 635f and a second downstream filter 636f. The first downstream filter 635f may be disposed in the first branch fluid line 6221f. The first downstream filter 635f may be disposed in a downstream side of the first downstream valve 632f. The second downstream filter 636f may be disposed in the second branch fluid line 6222f. The second downstream filter 636f may be disposed in a downstream side of the second downstream valve 633f.

A pressure reducing fluid line 640f may be connected to the supply fluid line 620f. The pressure reducing fluid line 640f is branched from the supply fluid line 620f, and may enable the process fluid to be discharged out of the supply fluid line 620f. The pressure reducing fluid line 640f may be connected to the supply fluid line 620f in a section between the upstream valve 631f and the downstream valves 632f and 633f. The pressure reducing fluid line 640f may be connected to the supply fluid line 620f in a section between the upstream filter 634f and the downstream valves 632f and 633f. The pressure reducing fluid line 640f may be connected to the main fluid line 6210f in a downstream section of the upstream filter 634f.

A pressure reducing valve 641f may be located on the pressure reducing fluid line 640f.

A vent fluid line 660f may be connected to the drying housing 600f. A vent valve 661f may be located on the vent fluid line 660f.

In addition, in the same or similar way as described in FIG. 11 to FIG. 13, the extension portion may be located on the main fluid line 6210f, and the repeated description thereon will not be redundantly included herein.

In addition, in the same or similar way as described in FIG. 10, a safety fluid line 650f may be connected to the supply fluid line 620f. The safety fluid line 650f may be connected to the main fluid line 6210f. The safety fluid line 650f may be connected to a section between the upstream valve 631f and the upstream filter 634f. A safety valve 651f may be located on the safety fluid line 650f. In addition, in the same or similar way as described in FIG. 9, the safety fluid line 650f may be connected to the pressure reducing fluid line 640f. In addition, the safety fluid line 650f may be omitted.

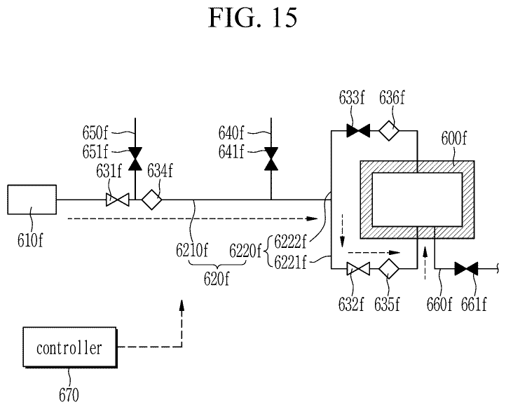

FIG. 15 is a drawing that represents a state in which a process fluid is supplied to the drying housing 600f in the pressure boosting step S1 described in FIG. 4.

Referring to FIG. 15, at the pressure boosting step S1, the upstream valve 631f and the first downstream valve 632f may be opened, and the second downstream valve 633f may be in the closed state. Accordingly, the process fluid may be supplied from the process fluid supply 610f to the lower portion of the drying housing 600f through the main fluid line 6210f and the first branch fluid line 6221f. At this time, the pressure reducing valve 641f may maintain the closed state, and the process fluid may be blocked from flowing from the supply fluid line 620f to the pressure reducing fluid line 640f. In addition, the vent valve 661f may maintain the closed state, and the discharge of the process fluid through the vent fluid line 660f may be blocked. As time passes while the process fluid is supplied to the drying housing 600f, an internal pressure of the drying housing 600f may increase. The supply of the process fluid may be made until the internal pressure of the drying housing 600f reaches the first pressure P1. In the pressure boosting step S1, the flow amount of the process fluid flowing along the main fluid line 6210f and the first branch fluid line 6221f may be the same, or may vary according to time.

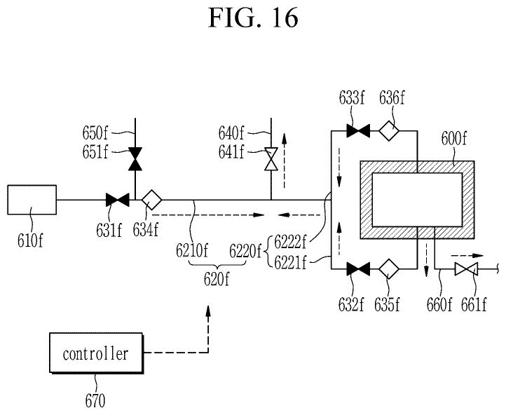

FIG. 16 is a drawing that represents a state in which pressure reduction is being made in an interior of the drying housing 600f in the flow step S2 described in FIG. 4.

Referring to FIG. 16, when the internal pressure of the drying housing 600f reaches the first pressure P1, the upstream valve 631f and the downstream valves 632f and 633f may be closed, and the supply of the process fluid from the process fluid supply 610f to the drying housing 600f may be blocked. In addition, the vent valve 661f may be opened, and the interior of the drying housing 600f may be discharged through the vent fluid line 660f. Accordingly, the internal pressure of the drying housing 600f is lowered. The discharge of the process fluid through the vent fluid line 660f may be made until the internal pressure of the drying housing 600f reaches the predetermined pressure, or may be made for a preset time.

In the state that the supply of the process fluid from the process fluid supply 610f to the drying housing 600f is blocked, the pressure reducing valve 641f may be opened, and the process fluid may flow from the supply fluid line 620f toward the pressure reducing fluid line 640f. Specifically, in the state that the upstream valve 631f and the downstream valves 632f and 633f are closed, the pressure reducing valve 641f may be opened. Accordingly, the process fluid remaining in a section between the upstream valve 631f and the downstream valves 632f and 633f may be discharged through the pressure reducing fluid line 640f. In the state that the supply of the process fluid to the drying housing 600f is blocked as the valves 631f, 632f, and 633f are closed, the time when the pressure reducing valve 641f is open may be the same as the time when the vent valve 661f is open. That is, when the interior of the drying housing 600f is discharged through the vent fluid line 660f, the discharge of the process fluid remaining in the supply fluid line 620f may be made through the pressure reducing fluid line 640f. In addition, in the state that the supply of the process fluid to the drying housing 600f is blocked as the valves 631f, 632f, and 633f are closed, the time when the pressure reducing valve 641f is open may be different from the time when the vent valve 661f is open. That is, when the interior of the drying housing 600f is discharged through the vent fluid line 660f, the pressure reducing valve 641f may be open during the time corresponding to a part of the time when the vent valve 661f is open.

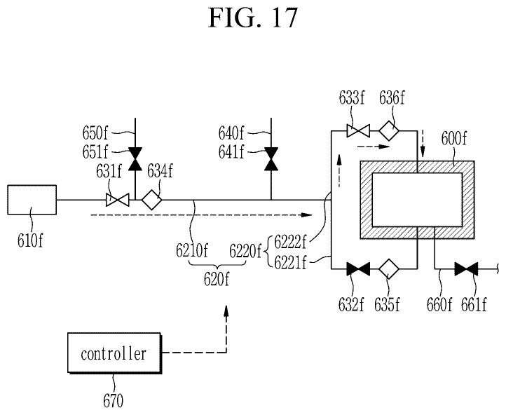

FIG. 17 is a drawing that represents a state in which a process fluid is supplied to the drying housing 600f in the flow step S2 described in FIG. 4.

Referring to FIG. 17, at the flow step S2, the upstream valve 631f and the second downstream valve 633f may be opened, and the first downstream valve 632f may be in the closed state. Accordingly, the process fluid may be supplied from the process fluid supply 610f to the upper portion of the drying housing 600f through the main fluid line 6210f and the second branch fluid line 6222f. In addition, the pressure reducing valve 641f may be closed, and the process fluid may be blocked from escaping through the pressure reducing fluid line 640f. In addition, the vent valve 661f may be closed, and the interior of the drying housing 600f may be blocked from being discharged. Accordingly, the pressure of the drying housing 600f may increase.

The supply of the process fluid may be made until the internal pressure of the drying housing 600f reaches the predetermined pressure, or may be made for a preset time.

During the flow step S2, the process described in FIG. 16 and FIG. 17 may be repeated at least once. Accordingly, during the flow step S2, the internal pressure of the drying housing 600f may maintain a pressure between the first pressure P1 and the second pressure P2. In addition, during the process of discharging the interior of the drying housing 600f and supplying the process fluid to the interior of the drying housing 600f, a flow of the process fluid may occur in the interior of the drying housing 600f.

In addition, during the time when the supply of the process fluid through the supply fluid line 620f is stopped, the process fluid remaining in the supply fluid line 620f may be discharged through the pressure reducing fluid line 640f. Accordingly, when the process fluid is supplied again to the drying housing 600f, flowing of the process fluid in the gas state into the drying housing 600f may be prevented or minimized.

Thereafter, when the vent step S3 is initiated, the vent valve 661f may be opened, and the interior of the drying housing 600f may be discharged. During the vent step S3, the valves 631f, 632f, and 633f may maintain the closed state, and the supply of the process fluid to the drying housing 600f may be blocked. In addition, during the vent step S3, the pressure reducing valve 641f may be in the closed state.

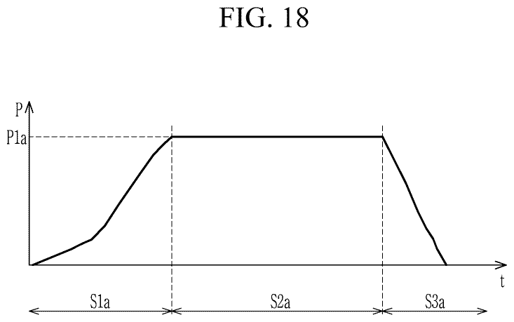

FIG. 18 is a drawing that represents an internal pressure change of the drying housing 600f, while the drying process is performed according to another embodiment.

Referring to FIG. 18, while the drying process according to another embodiment is being processed, the internal pressure of the drying housing 600f may change in a sequence of a pressure boosting step S1a, a flow step S2a, and a vent step S3a.

At the pressure boosting step S1a, the internal pressure of the drying housing 600f may be increased. For example, at the pressure boosting step S1a, the internal pressure of the drying housing 600f may be increased to a first pressure P1a. The first pressure P1a may be a value exceeding the threshold pressure of the process fluid. For example, the first pressure P1a may be 150 bar.

At the flow step S2a, the internal pressure of the drying housing 600f may maintain a pressure belonging to a predetermined range. At the flow step S2a, the internal pressure of the drying housing 600f may maintain a value exceeding the threshold pressure of the process fluid. At the flow step S2a, the change of the internal pressure of the drying housing 600f may be smaller than the pressure change at the flow step S2 described in FIG. 4. For example, at the flow step S2a, the internal pressure of the drying housing 600f may be generally parallel to a horizontal axis.

At the vent step S3a, the internal pressure of the drying housing 600f is lowered. At the vent step S3a, the internal pressure of the drying housing 600f may be lowered below the threshold pressure of the process fluid. For example, at the vent step S3a, the internal pressure of the drying housing 600f may be lowered to a normal pressure.

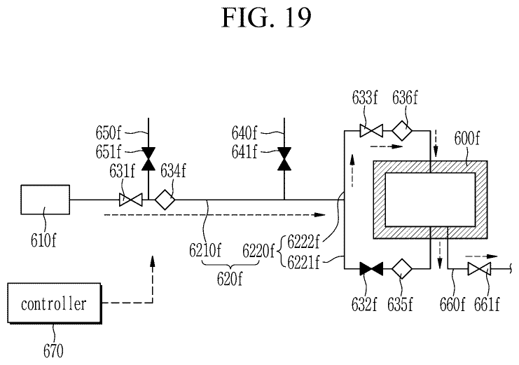

FIG. 19 is a drawing that represents a state in which a process fluid is supplied to the drying housing 600f in the flow step S2a described in FIG. 18.

First, at the pressure boosting step S1a described in FIG. 18, the process fluid may be supplied from the process fluid supply 610f to the lower portion of the drying housing 600f. The operation state at this time may be the same as described in FIG. 15, and the repeated description will not be redundantly included herein.

Thereafter, when the flow step S2a is initiated, similarly to the operation state described in FIG. 16, in the state that the supply of the process fluid to the drying housing 600f is stopped as the valves 631f, 632f, and 633f is closed, the pressure reducing valve 641f may be opened, and the process fluid remaining in the supply fluid line 620f may be discharged through the pressure reducing fluid line 640f. When the process fluid is discharged through the pressure reducing fluid line 640f as the pressure reducing valve 641f is opened, the vent valve 661f may be in an open state, which is the same as in FIG. 16. In addition, when the process fluid is discharged through the pressure reducing fluid line 640f as the pressure reducing valve 641f is opened, the vent valve 661f may be in the closed state, which is different from FIG. 16.

Thereafter, as shown in FIG. 19, at the flow step S2a, the upstream valve 631f and the second downstream valve 633f may be opened, and the first downstream valve 632f may be in the closed state. Accordingly, the process fluid may be supplied from the process fluid supply 610f to the upper portion of the drying housing 600f through the main fluid line 6210f and the second branch fluid line 6222f. In addition, the pressure reducing valve 641f may be closed, and the process fluid may be blocked from escaping through the pressure reducing fluid line 640f. In addition, the vent valve 661f may be opened, and the interior of the drying housing 600f may be discharged. At this time, the amount of fluid discharged through the vent fluid line 660f may correspond to the amount of the process fluid supplied from the process fluid supply 610f to the interior of the drying housing 600f. Accordingly, during the flow step S2a, the internal pressure of the drying housing 600f may maintain the pressure belonging to a predetermined range.

Thereafter, when the vent step S3a is initiated, the vent valve 661f may be opened, and the interior of the drying housing 600f may be discharged. During the vent step S3a, the valves 631f, 632f, and 633f may maintain the closed state, and the supply of the process fluid to the drying housing 600f may be blocked. In addition, during the vent step S3f, the pressure reducing valve 641f may be in the closed state.

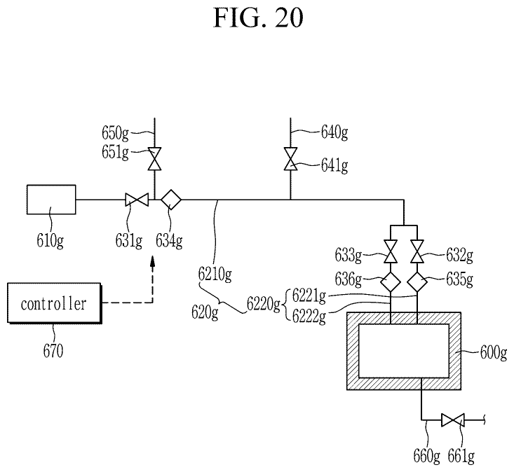

FIG. 20 is a drawing that represents a fluid line structure connected to a drying housing 600g according to another embodiment.

Referring to FIG. 20, the drying housing 600g may be connected to a process fluid supply 610g through a supply fluid line 620g. Hereinafter, repeated description on the part that is the same as or similar to that described in FIG. 3 to FIG. 8 will not be redundantly included herein, and the description will focus on the differences.

The supply fluid line 620g may include a main fluid line 6210g and a branch fluid line 6220g.

A first end of the main fluid line 6210g may be connected to the process fluid supply 610g.

A first end of the branch fluid line 6220g may be connected to a second end of the main fluid line 6210g. A second end of the branch fluid line 6220g may be connected to the drying housing 600g. The branch fluid line 6220g may include a first branch fluid line 6221g and a second branch fluid line 6222g. The first branch fluid line 6221g and the second branch fluid line 6222g is branched from the second end of the main fluid line 6210g, and may be connected to the drying housing 600g in a in parallel structure. A second end of the first branch fluid line 6221g may be connected to an upper portion of the drying housing 600g. For example, the second end of the first branch fluid line 6221g may be connected to an upper wall of the drying housing 600g. A second end of the second branch fluid line 6222g may be connected to the upper portion of the drying housing 600g. For example, the second end of the second branch fluid line 6222g may be connected to an upper wall of the drying housing 600g.

Valves 631g, 632g, and 633g may be disposed in the supply fluid line 620g. The valves 631g, 632g, and 633g may include an upstream valve 631g and the downstream valves 632g and 633g. The upstream valve 631g and the downstream valves 632g and 633g may be disposed to be spaced apart from each other on the supply fluid line 620g. The upstream valve 631g may be disposed in an upstream side of the downstream valves 632g and 633g. The upstream valve 631g may be disposed in the main fluid line 6210g.

The downstream valves 632g and 633g may be disposed in the branch fluid line 6220g. The downstream valves 632g and 633g may include a first downstream valve 632g and a second downstream valve 633g. The first downstream valve 632g may be disposed in the first branch fluid line 6221g. The second downstream valve 633g may be disposed in the second branch fluid line 6222g.

Filters 634g, 635g, and 636g may be disposed in the supply fluid line 620g. The filters 634g, 635g, and 636g may filter foreign substances included in the process fluid flowing through the supply fluid line 620g. The filters 634g, 635g, and 636g may include an upstream filter 634g and the downstream filters 635g and 636g. The upstream filter 634g may be disposed in the main fluid line 6210g. The upstream filter 634g may be disposed in a downstream side of the upstream valve 631g.

The downstream filters 635g and 636g may be disposed in the branch fluid line 6220g. The downstream filters 635g and 636g may include a first downstream filter 635g and a second downstream filter 636g. The first downstream filter 635g may be disposed in the first branch fluid line 6221g. The first downstream filter 635g may be disposed in a downstream side of the first downstream valve 632g. The second downstream filter 636g may be disposed in the second branch fluid line 6222g. The second downstream filter 636g may be disposed in a downstream side of the second downstream valve 633g.

A pressure reducing fluid line 640g may be connected to the supply fluid line 620g. The pressure reducing fluid line 640g is branched from the supply fluid line 620g, and may enable the process fluid to be discharged out of the supply fluid line 620g. The pressure reducing fluid line 640g may be connected to the supply fluid line 620g in a section between the upstream valve 631g and the downstream valves 632g and 633g. The pressure reducing fluid line 640g may be connected to the supply fluid line 620g in a section between the upstream filter 634g and the downstream valves 632g and 633g. The pressure reducing fluid line 640g may be connected to the main fluid line 6210g in a downstream section of the upstream filter 634g.

A pressure reducing valve 641g may be located on the pressure reducing fluid line 640g.

A vent fluid line 660g may be connected to the drying housing 600g. A vent valve 661g may be located on the vent fluid line 660g.

In addition, in the same or similar way as described in FIG. 11 to FIG. 13, the extension portion may be located on the main fluid line 6210g, and the repeated description thereon will not be redundantly included herein.

In addition, in the same or similar way as described in FIG. 10, a safety fluid line 650g may be connected to the supply fluid line 620g. The safety fluid line 650g may be connected to the main fluid line 6210g. The safety fluid line 650g may be connected to a section between the upstream valve 631g and the upstream filter 634g. A safety valve 651g may be located on the safety fluid line 650g. In addition, in the same or similar way as described in FIG. 9, the safety fluid line 650g may be connected to the pressure reducing fluid line 640g. In addition, the safety fluid line 650g may be omitted.

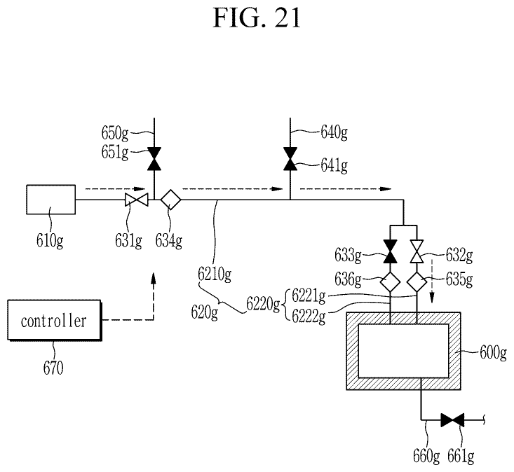

FIG. 21 is a drawing that represents a state in which a process fluid is supplied to the drying housing 600g in the pressure boosting step S1 described in FIG. 4 or the pressure boosting step S1a described in FIG. 18.

Referring to FIG. 21, at the pressure boosting steps S1 and S1a, the upstream valve 631g and the first downstream valve 632g may be opened, and the second downstream valve 633g may be in the closed state. Accordingly, the process fluid may be supplied from the process fluid supply 610g to the upper portion of the drying housing 600g through the main fluid line 6210g and the first branch fluid line 6221g. At this time, the pressure reducing valve 641g may maintain the closed state, and the process fluid may be blocked from flowing from the supply fluid line 620g to the pressure reducing fluid line 640g. In addition, the vent valve 661g may maintain the closed state, and the discharge of the process fluid through the vent fluid line 660g may be blocked. As time passes while the process fluid is supplied to the drying housing 600g, an internal pressure of the drying housing 600g may increase. The supply of the process fluid may be made until the internal pressure of the drying housing 600g reaches the first pressures P1 and P1a. In the pressure boosting steps S1 and S1a, the flow amount of the process fluid flowing along the main fluid line 6210g and the first branch fluid line 6221g may be the same, or may vary according to time.

Thereafter, when the flow steps S2 and S2a is initiated, similarly to the operation state described in FIG. 16, the pressure reducing valve 641g may be opened, and the process fluid remaining in the supply fluid line 620g may be discharged through the pressure reducing fluid line 640g. When the process fluid is discharged through the pressure reducing fluid line 640g as the pressure reducing valve 641g is opened, the vent valve 661g may be in the open state, which is the same as in FIG. 16. In addition, when the process fluid is discharged through the pressure reducing fluid line 640g as the pressure reducing valve 641g is opened, the vent valve 661g may be in the closed state, which is different from FIG. 16.

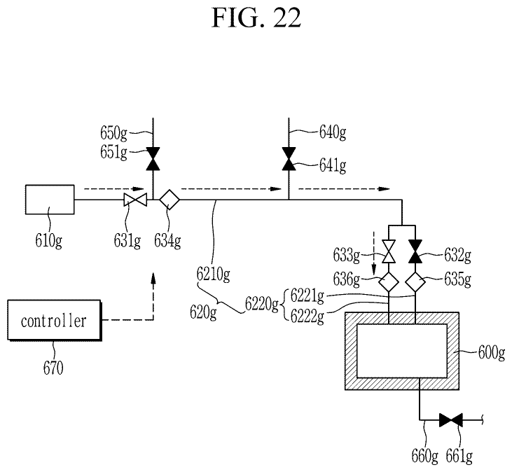

FIG. 22 is a drawing that represents a state in which a process fluid is supplied to the drying housing in the flow steps S2 and S2a.

Thereafter, as shown in FIG. 22, at the flow steps S2 and S2a, the upstream valve 631g and the second downstream valve 633g may be opened, and the first downstream valve 632g may be in the closed state. Accordingly, the process fluid may be supplied from the process fluid supply 610g to the upper portion of the drying housing 600g through the main fluid line 6210g and the second branch fluid line 6222g. In addition, the pressure reducing valve 641g may be closed, and the process fluid may be blocked from escaping through the pressure reducing fluid line 640g.

At this time, the vent valve 661g may become the closed state, and the pressure in an interior of the drying housing 600g may increase. In addition, in the same or similar way as described in FIG. 16 and FIG. 17, at the flow step S2, the process of discharging the interior of the drying housing 600g and supplying the process fluid to the interior of the drying housing 600g may be repeated at least once. Accordingly, at the flow step S2, the internal pressure of the drying housing 600g may be as described above in FIG. 4.

In addition, in the same or similar way as described in FIG. 19, the vent valve 661g may be opened, and the interior of the drying housing 600g may be discharged. At this time, the amount of fluid discharged through the vent fluid line 660g may correspond to the amount of the process fluid supplied from the process fluid supply 610g to the interior of the drying housing 600g. Accordingly, during the flow step S2a, the internal pressure of the drying housing 600g may maintain the pressure belonging to a predetermined range. Accordingly, at the flow step S2a, the internal pressure of the drying housing 600g may be as described above in FIG. 18.

Thereafter, when the vent steps S3 and S3a is initiated, the vent valve 661g may be opened, and the interior of the drying housing 600g may be discharged. During the vent step S3g, the valves 631g, 632g, and 633g may maintain the closed state, and the supply of the process fluid to the drying housing 600g may be blocked. In addition, during the vent steps S3 and S3a, the pressure reducing valve 641g may be the closed state.

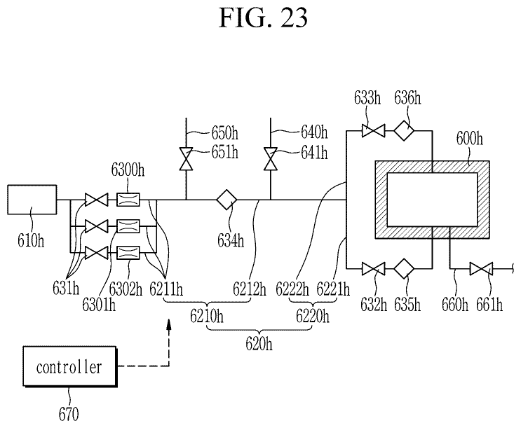

FIG. 23 is a drawing that represents a fluid line structure connected to a drying housing 600h according to another embodiment.

Referring to FIG. 23, the drying housing 600h may be connected to a process fluid supply 610h through a supply fluid line 620h. Hereinafter, repeated description on the part that is the same as or similar to that described in FIG. 16 to FIG. 19 will not be redundantly included herein, and the description will focus on the differences.

The supply fluid line 620h may include a main fluid line 6210h and a branch fluid line 6220h.

A first end of the main fluid line 6210h may be connected to the process fluid supply 610h. The main fluid line 6210h may include a plurality of flow control fluid lines 6211h and a connection fluid line 6212h.

First ends of the plurality of flow control fluid lines 6211h may be connected to the process fluid supply 610h. The plurality of flow control fluid lines 621 1h may be disposed in parallel to each other. The connection fluid line 6212h may connect the plurality of flow control fluid lines 6211h and the branch fluid line 6220h. That is, a first end of the connection fluid line 6212h may be connected to second ends of the plurality of flow control fluid lines 6211h, and a second end of the connection fluid line 6212h may be connected to a first end of the branch fluid line 6220h. Orifices 6300h, 6301h, and 6302h may be disposed in the plurality of flow control fluid lines 6211, respectively. The orifices 6300h, 6301h, and 6302h each located in the plurality of flow control fluid lines 6211h may be provided to have different internal passage areas through which the process fluid flows.

The branch fluid line 6220h may connect a second end of the main fluid line 6210h and the drying housing 600h. The first end of the branch fluid line 6220h may be connected to the second end of the connection fluid line 6212h, and a second end of the branch fluid line 6220h may be connected to the drying housing 600h.

The branch fluid line 6220h may include a first branch fluid line 6221h and a second branch fluid line 6222h. The first branch fluid line 6221h and a second branch fluid line 6221h is branched from the second end of the main fluid line 6210h, and may be connected to the drying housing 600h in a parallel structure. A second end of the first branch fluid line 6221h may be connected to a lower portion of the drying housing 600h. For example, the second end of the first branch fluid line 6221h may be connected to a lower wall of the drying housing 600h. A second end of the second branch fluid line 6222h may be connected to an upper portion of the drying housing 600h. For example, the second end of the second branch fluid line 6222h may be connected to an upper wall of the drying housing 600h.

Unlike this, the second end of the first branch fluid line 6221h may be connected to the upper portion of the drying housing 600h, which is the same as in FIG. 20. For example, the second end of the first branch fluid line 6221h may be connected to an upper wall of the drying housing 600h.

Valves 631h, 632h, and 633h may be disposed in the supply fluid line 620h. The valves 631h, 632h, and 633h may include an upstream valve 631h and the downstream valves 632h and 633h. The upstream valve 631h and the downstream valves 632h and 633h may be disposed to be spaced apart from each other on the supply fluid line 620h. The upstream valve 631h may be disposed in an upstream side of the downstream valves 632h and 633h. The upstream valve 631h may be disposed in the main fluid line 6210h. The upstream valve 631h may be provided in a plural quantity, and disposed in the plurality of flow control fluid lines 6211h, respectively. The upstream valve 631h may be disposed in an upstream side of the orifices 6300h, 6301h, and 6302h.

The downstream valves 632h and 633h may be disposed in the branch fluid line 6220h. The downstream valves 632h and 633h may include a first downstream valve 632h and a second downstream valve 633h. The first downstream valve 632h may be disposed in the first branch fluid line 6221h. The second downstream valve 633h may be disposed in the second branch fluid line 6222h.

Filters 634h, 635h, and 636h may be disposed in the supply fluid line 620h. The filters 634h, 635h, and 636h may filter foreign substances included in the process fluid flowing through the supply fluid line 620h. The filters 634h, 635h, and 636h may include an upstream filter 634h and the downstream filters 635h and 636h. The upstream filter 634h may be disposed in the main fluid line 6210h. The upstream filter 634h may be disposed in a downstream side of the upstream valve 631h. The upstream filter 634h may be disposed in the connection fluid line 6212h.

The downstream filters 635h and 636h may be disposed in the branch fluid line 6220h. The downstream filters 635h and 636h may include a first downstream filter 635h and a second downstream filter 636h. The first downstream filter 635h may be disposed in the first branch fluid line 6221h. The first downstream filter 635h may be disposed in a downstream side of the first downstream valve 632h. The second downstream filter 636h may be disposed in the second branch fluid line 6222h. The second downstream filter 636h may be disposed in a downstream side of the second downstream valve 633h.

A pressure reducing fluid line 640h may be connected to the supply fluid line 620h. The pressure reducing fluid line 640h is branched from the supply fluid line 620h, and may enable the process fluid to be discharged out of the supply fluid line 620h. The pressure reducing fluid line 640h may be connected to the supply fluid line 620h in a section between the upstream valve 631h and the downstream valves 632h and 633h. The pressure reducing fluid line 640h may be connected to the supply fluid line 620h in a section between the upstream filter 634h and the downstream valves 632h and 633h. The pressure reducing fluid line 640h may be connected to the connection fluid line 6212h. The pressure reducing fluid line 640h may be connected to the connection fluid line 6212h in a downstream section of the upstream filter 634h.

A pressure reducing valve 641h may be located on the pressure reducing fluid line 640h.

A vent fluid line 660h may be connected to the drying housing 600h. A vent valve 661h may be located on the vent fluid line 660h.

In addition, in the same or similar way as described in FIG. 11 to FIG. 13, the extension portion may be located on the connection fluid line 6212h, and the repeated description thereon will not be redundantly included herein.

In addition, in the same or similar way as described in FIG. 10, a safety fluid line 650h may be connected to the supply fluid line 620h. The safety fluid line 650h may be connected to the connection fluid line 6212h. The safety fluid line 650h may be connected to an upstream side of the upstream filter 634h. A safety valve 651h may be located on the safety fluid line 650h. In addition, in the same or similar way as described in FIG. 9, the safety fluid line 650h may be connected to the pressure reducing fluid line 640h. In addition, the safety fluid line 650h may be omitted.

When the process fluid is supplied from the process fluid supply 610h to the drying housing 600h, at least one of a plurality of upstream valves 631h is opened. When the process fluid is not supplied from the process fluid supply 610h to the drying housing 600h, the plurality of upstream valves 631h are all closed.

Except that the upstream valve 631h is provided in a plural quantity such that at least one among the plurality of upstream valves 631h is opened when the process fluid is supplied and the plurality of upstream valves 631h are all closed when the process fluid is not supplied from the process fluid supply 610h to the drying housing 600h, the method in which the process fluid is supplied to an interior of the drying housing 600h through a fluid line connected to the drying housing 600h while the drying process is being performed or the interior of the drying housing 600h is discharged is the same as or similar to as described in FIG. 15 to FIG. 19, of which the repeated description will not be redundantly included herein.

While the embodiment of the present disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

### Description of Symbols

2: index module
3: process module
20: load port
22: transport
30: buffer chamber
40: transport chamber
50: liquid processing chamber
60: drying chamber
500: liquid processing housing
510: support plate
520: fluid supply
600: drying housing
610: process fluid supply
620: supply fluid line
631: upstream valve
632: downstream valve
640: pressure reducing fluid line
641: pressure reducing valve
660: vent fluid line
661: vent valve

1. A substrate processing apparatus, comprising:
a drying housing having an internal space for performing a drying process;
a process fluid supply configured to receive a process fluid used in the drying process;
a supply fluid line connected to the drying housing and connected to the process fluid supply;
a pressure reducing fluid line connected to the supply fluid line; and
a controller configured to control the operation of the substrate processing apparatus,
wherein, the controller is configured to initiate a drying process and, after the drying process is initiated, cause the supply of the process fluid to the drying housing through the supply fluid line to stop and cause the process fluid remaining in the supply fluid line to discharge through the pressure reducing fluid line.

2. The substrate processing apparatus of claim 1, comprising:
an upstream valve disposed in the supply fluid line; and
a downstream valve disposed in the supply fluid line on a downstream side of the upstream valve,
wherein the pressure reducing fluid line is connected to a section of the supply fluid line between the upstream valve and the downstream valve.

3. The substrate processing apparatus of claim 2, wherein the supply fluid line comprises an extension portion having a cross section of an interior space along a direction perpendicular to a length direction of the supply fluid line is greater than that of an adjacent region of the supply fluid line.

4. The substrate processing apparatus of claim 3, wherein the extension portion is located in a section between the upstream valve and the downstream valve.

5. The substrate processing apparatus of claim 2, wherein the supply fluid line comprises:
a main fluid line having a first end connected to the process fluid supply;
a first branch fluid line having a first end connected to a second end of the main fluid line, and a second end connected to the drying housing; and
a second branch fluid line having a first end connected to the second end of the main fluid line, and a second end connected to the drying housing.

6. The substrate processing apparatus of claim 5, wherein:
the upstream valve is disposed in the main fluid line; and
the downstream valve is
a first downstream valve disposed in the first branch fluid line, and the substrate processing apparatus further comprises a second downstream valve disposed in the second branch fluid line.

7. The substrate processing apparatus of claim 5, wherein the pressure reducing fluid line is connected to the main fluid line.

8. The substrate processing apparatus of claim 5, wherein the main fluid line comprises:
a plurality of flow control fluid lines disposed in parallel to each other, and each flow control fluid line having a first end connected to the process fluid supply and a second end; and
a connection fluid line having a first end connected to the second end of each of the plurality of flow control fluid lines, and a second end connected to a first end of the first branch fluid line and a first end of the second branch fluid line.

9. The substrate processing apparatus of claim 8, further comprising a plurality of upstream valves, wherein the upstream valve is a first upstream valve of the plurality of upstream valves, and each upstream valve of the plurality is disposed in a respective one of the plurality of flow control fluid lines.

10. The substrate processing apparatus of claim 5, wherein:
a second end of the first branch fluid line is connected to a lower portion of the drying housing; and
a second end of the second branch fluid line is connected to an upper portion of the drying housing.

11. The substrate processing apparatus of claim 5, wherein:
a second end of the first branch fluid line is connected to an upper portion of the drying housing; and
a second end of the second branch fluid line is connected to the upper portion of the drying housing.

12. The substrate processing apparatus of claim 1, further comprising a safety fluid line connected to the supply fluid line.

13. A substrate processing apparatus, comprising:
a drying housing having an internal space for performing a drying process;
a process fluid supply configured to receive a process fluid used in the drying process;
a supply fluid line connected to the drying housing and connected to the process fluid supply;
a pressure reducing fluid line connected to the supply fluid line; and
a controller configured to control the operation of the substrate processing apparatus,
wherein, the controller is configured to stop a supply of the process fluid to the drying housing after an internal pressure of the drying housing has reached a first threshold pressure and discharge, process fluid remaining in the supply fluid line through the pressure reducing fluid line before resupplying the process fluid to the drying housing.

14. The substrate processing apparatus of claim 13, wherein the supply fluid line comprises:
a main fluid line having a first end connected to the process fluid supply;
a first branch fluid line having a first end connected to a second end of the main fluid line, and a second end connected to the drying housing; and
a second branch fluid line having a first end connected to the second end of the main fluid line, and a second end connected to the drying housing.,
wherein, the controller is configured to supply the process fluid to the drying housing through the first branch fluid line until the first threshold pressure is reached, and switch the supply of the process fluid to the housing to the second branch fluid line after the threshold pressure is reached.

15. A substrate processing apparatus, comprising:
a drying housing having an internal space for performing a drying process;
a process fluid supply configured to receive a process fluid used in the drying process;
a supply fluid line connected to the drying housing and connected to the process fluid supply; and
a pressure reducing fluid line connected to the supply fluid line,
wherein the supply fluid line comprises:
a main fluid line having a first end connected to the process fluid supply;
a first branch fluid line having a first end connected to a second end of the main fluid line, and a second end connected to the drying housing; and
a second branch fluid line having a first end connected to the second end of the main fluid line, and a second end connected to the drying housing,
wherein, the pressure reducing fluid line provides a fluid path for the process fluid to discharge from the supply fluid line.

16. The substrate processing apparatus of claim 15, wherein the pressure reducing fluid line is connected to the main fluid line.

17. The substrate processing apparatus of claim 16, wherein an extension portion of the supply fluid line has a cross section along a direction perpendicular to a length direction of the supply fluid line is greater than that of an adjacent region disposed in the main fluid line.

18. The substrate processing apparatus of claim 17, wherein the extension portion is disposed at an upstream side of a location where the pressure reducing fluid line is connected to the main fluid line.

19. The substrate processing apparatus of claim 17, wherein the extension portion is disposed in a downstream side of a location where the pressure reducing fluid line is connected to the main fluid line.

20. The substrate processing apparatus of claim 17, wherein the pressure reducing fluid line is connected to the extension portion.

21-23. (canceled)
